(19) United States
(12) Patent Application Publication
(10) Pub. No.: US 2008/0067923 A1
(43) Pub. Date: Mar. 20, 2008

(54) TRANSPARENT ELECTRODE SURFACE-TREATED USING INDIUM ANTIMONIDE AND METHOD OF SURFACE-TREATING TRANSPARENT ELECTRODE

(75) Inventors: Young Soo Yoon, Gyeonggi-do (KR); Seung Hyun Jee, Gyeonggi-do (KR); Soo Ho Kim, Incheon (KR); Jae Hwan Ko, Gyeonggi-do (KR)

Correspondence Address: ADAM K. SACHAROFF;MUCH SHELIST FREED DENENBERG AMENT&RUBENSTEIN,PC, 191 N. WACKER DRIVE, SUITE 1800, CHICAGO, IL, 60606-1615, US

(73) Assignee: KONKUK UNIVERSITY INDUSTRIAL COOPERATION CORP., Seoul (KR)

(21) Appl. No.: 11/697,855

(22) Filed: Apr. 9, 2007

(30) Foreign Application Priority Data
Sep. 19, 2006 (KR) 10-2006-0090658

(51) Int. Cl. H01L 21/00

(52) U.S. Cl. 313/504; 438/22; 257/E21.002

(57) ABSTRACT

A transparent electrode for use in display devices, such as OLEDs and OTFTs, is provided. The transparent electrode includes an indium antimonide (InSb) layer having a predetermined thickness on the surface thereof. The transparent electrode is imparted with an increased work function without changing light transmittance.

### BACKGROUND OF THE INVENTION

1. Field of the Invention

The present invention relates, generally, to a transparent electrode for use in display devices, such as OLEDs and OTFTS, and more particularly, to a transparent electrode, which is surface-treated using indium antimonide (InSb), in order to increase the work function thereof, and to a method of surface-treating a transparent electrode.

2. Description of the Related Art

Typically, since ITO (Indium Tin Oxide) has high transmittance in the visible light range and excellent electrical conductivity and is easily prepared, it is presently useful as a transparent electrode in the field of various display devices and electronic devices, such as solar cells. In particular, as the electrode of an OLED (Organic light emitting diode) and an OTFT (organic thin film transistor), which are regarded as technology for next-generation displays, an ITO transparent electrode is used in the form of a film.

In the fabrication of the display device, when holes are injected to the light-emitting layer of the OLED or the organic semiconductor, a large energy barrier is present between the transparent electrode and the organic semiconductor. Therefore, it is preferred that the work function (electrical properties) of the transparent electrode be set so that it is almost the same as the work function of the organic compound that constitutes the corresponding light-emitting layer or organic semiconductor, to thus minimize the energy barrier between the transparent electrode and the organic semiconductor.

In order to decrease the energy barrier, the difference in ionization potential between the transparent electrode and the organic compound of the organic semiconductor should be reduced. The hole transport layer used in the OLED and the organic semiconductor used in the OTFT has a work function of about 5.1˜5.5 eV. In consideration of the fact that the work function of ITO typically falls in the range of 4.5˜4.6 eV, a very large energy barrier can be confirmed to be present between the ITO and the organic semiconductor.

To solve the problems, ITO may be replaced with another material having a work function that is higher than ITO. However, materials that are able to satisfy requirements for replacement, for example, light transmittance, process convenience, price, etc., have not yet been found.

### SUMMARY OF INVENTION

Accordingly, the present invention has been made keeping in mind the problems encountered in the prior art, and an object of the present invention is to provide a transparent electrode, which has an increased work function without also having changed light transmittance.

The above object is accomplished by depositing indium antimonide (InSb) on the surface of a transparent electrode (ITO).

The above and other objects, features and other advantages of the present invention will be more clearly understood from the following detailed description taken in conjunction with the accompanying drawing. As such, it should be noted that the detailed description of the known functions and structures related to the present invention has been omitted in order to avoid ambiguity in the present invention.

### BRIEF DESCRIPTION OF THE DRAWING

FIG. 1 is a graph showing the changes in light transmittance in the test example of the present invention.

### DESCRIPTION OF THE PREFERRED EMBODIMENT

Useful in the present invention, indium antimonide (InSb) has much higher electron mobility than silicon (Si) and other compound semiconductors. Further, it has an energy gap of 0.17 eV, and thus is applied in hole devices using fast electron mobility.

Furthermore, compared to other metals and semiconductors, indium antimonide has a relatively high work function of 5.6 eV, therefore making it possible to decrease the energy barrier due to the difference in work function, as mentioned above. For more specific characteristics of indium antimonide, reference may be made to the prior work “Crag R. Barrett, William D. Nix, Alan S. Tetelman, The Principles of Engineering Materials, p438, 1973”.

According to the present invention, a transparent electrode (ITO) comprises an indium antimonide layer (or an indium antimonide film) deposited to a predetermined thickness on the surface thereof.

Below, the electrical properties (work function) and light transmittance of the transparent electrode deposited with indium antimonide are analyzed, in order to evaluate the superiority thereof.

### TEST EXAMPLE

1. Deposition of Indium Antimonide

The surface of an ITO transparent electrode was cleaned to remove impurities therefrom, and was then deposited with indium antimonide (InSb). For this, a typical thermal evaporation process was used. Specifically, an ingot of indium antimonide having a weight of 1 g was used for deposition, which was conducted at a rate of 2.4 nm/sec in a vacuum level of 10⁻⁶ mmHg for 1˜2 sec.

2. Analysis of Properties (Work Function and Light Transmittance)

In the case where the electrode was not subjected to surface modification through deposition using indium antimonide, the work function thereof was measured to be about 4.5 ev. However, in the case where the electrode was subjected to surface modification, the work function thereof was measured to be 4.798˜4.842 eV. The results of changes in work function depending on the InSb deposition time of 1 sec and 2 sec are shown in Table 1 below.

TABLE 1

| Deposition | Deposition Rate | | |
|---|---|---|---|
| Time (sec) | (nm/sec) | Work Function (eV) | Increase (eV) |
| 1 | 2.4 | 4.842 | 0.245 |
| 2 | 2.4 | 4.798 | 0.201 |

As is apparent from Table 1, a work function corresponding to 5.6 eV, as mentioned above, was not attained. This was believed to be because portions of indium antimonide (InSb) were separated into indium (In) and antimony (Sb) and thus deposited by thermal energy applied upon thermal evaporation, whereby the work function did not reach the expected value.

However, the results of the above table sufficiently show the probability of efficiency realizing the injection of holes from the ITO by decreasing the energy barrier between the ITO and the organic semiconductor in the case where the work function of the organic semiconductor is 5.1˜5.5 eV. Furthermore, it is obvious that appropriately controlling the temperature of thermal evaporation and the composition ratio results in an increase in work function, coinciding with the expected value. In the test example of the invention, the work function was measured using a Kelvin probe. Such a Kelvin probe is a widely used device, thus a description thereof is omitted.

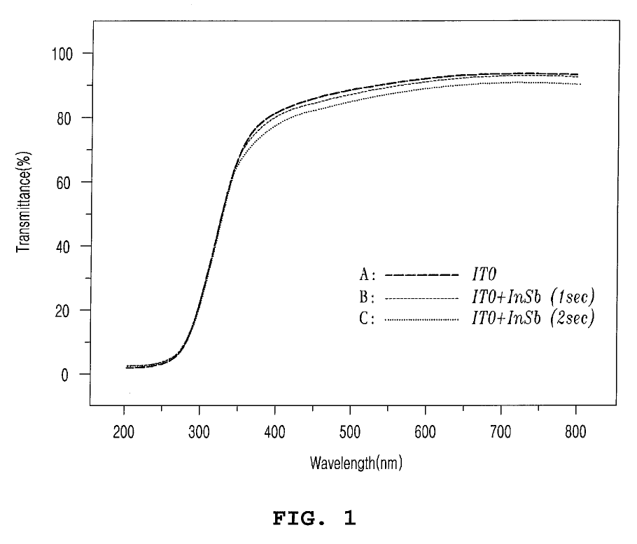

In addition, the light transmittance was observed to be the same, regardless of whether indium antimonide was deposited. That is, the ITO was suitable for use in the transparent electrode of the display device. The results are shown in FIG. 1.

In FIG. 1, the longitudinal axis indicates light transmittance, the transverse axis indicates wavelength, A is a curve showing the changes in properties of the ITO transparent electrode, and B and C are curves showing the changes in properties of the ITO transparent electrodes on which indium antimonide was deposited for 1 sec and 2 sec, respectively. As seen in FIG. 1, as the results of practical tests, the transmittance of the electrode having indium antimonide deposited thereon was observed to be decreased (B, C). However, the extent of the decrease in transmittance was very small. Furthermore, in consideration of the likelihood of inclusion of experimental error, it is reasonable to accept that there is virtually no change in light transmittance.

As described hereinbefore, the present invention provides a transparent electrode surface-treated using indium antimonide and a method of surface-treating a transparent electrode. According to the present invention, a transparent electrode is deposited with indium antimonide, and thereby the work function thereof can be increased without changing light transmittance.

Although the preferred embodiment of the present invention has been disclosed for illustrative purposes, those skilled in the art will appreciate that various modifications, additions and substitutions are possible, without departing from the scope and spirit of the invention as disclosed in the accompanying claims.

What is claimed is:

1. A transparent electrode for a display device, comprising an indium antimonide (InSb) layer deposited to a predetermined thickness on a surface of the transparent electrode (ITO) through a surface treatment using indium antimonide.

2. A method of surface-treating a transparent electrode for a display device, comprising depositing indium antimonide (InSb) to a predetermined thickness on a surface of the transparent electrode (ITO) to increase a work function of the transparent electrode.
